(19) United States
(12) Patent Application Publication
(10) Pub. No.: US 2025/0027899 A1
(43) Pub. Date: Jan. 23, 2025

(54) ELECTROCHEMISTRY MICROSCOPY BIPOLAR REFERENCE ELECTRODE ASSEMBLY

(71) Applicant: Protochips, Inc., Morrisville, NC (US)

(72) Inventors: Katherine Marusak Stephens, Garner, NC (US); Ryan Murphy, Clayton, NC (US); Nelson L. Marthe, JR., Cary, NC (US); Benjamin Bradshaw Larson, Cary, NC (US); Franklin Stampley Walden, II, Raleigh, NC (US); John Damiano, JR., Holly Springs, NC (US)

(21) Appl. No.: 18/778,522

(22) Filed: Jul. 19, 2024

Related U.S. Application Data
(60) Provisional application No. 63/514,975, filed on Jul. 21, 2023.

(51) Int. Cl. G01N 27/30; B81B 7/00

(52) U.S. Cl. CPC G01N 27/301; B81B 7/0006; B81B 2201/0292; B81B 2203/04

(57) ABSTRACT

A reference electrode assembly for electrochemistry microscopy samples includes a Micro-Electro-Mechanical Systems (MEMS) chip having a thin-film wire disposed on a surface thereof, a bridge electrode electrically connected to the thin-film wire through a Transmission Electron Microscope (TEM) holder, a portion of the bridge electrode disposed in contact with a sample solution contained within a vial and a standard reference electrode disposed within the vial and in contact with the sample solution, wherein the standard reference electrode electrically connects to a potentiostat maintaining the charge balance with a sample solution. The MEMS chip may be disposed within a holder tip connected with the TEM holder at an end thereof. A portion of the reference electrode assembly may be disposed within a Faraday cage to minimize the effect of noise on the reference potential.

### CROSS-REFERENCE TO RELATED APPLICATIONS

This application claims priority to U.S. Provisional Patent Application No. 63/514,975, which was filed on Jul. 21, 2023, the entire contents of which is hereby incorporated by reference in its entirety.

### TECHNICAL FIELD

The present disclosure relates to electrochemical probes, and more particularly to a reference electrode assembly to be utilized in a three-electrode electrochemical cell.

### BACKGROUND

Electrochemistry is the study of electricity and how it relates to chemical reactions. Electrochemistry and its principles constitute a fundamental basis for a variety of industries common and necessary to everyday life. Indeed, electrochemical reactions are commonly used in chemical manufacturing, and the combustion of hydrocarbons and corrosion of metals are common examples of oxidation-reduction reactions. Moreover, electrochemical technology based on electrochemistry also plays an important role in many modern manufacturing processes and products, especially in the fields of microtechnology, which has and continues to revolutionize almost all aspects of everyday life.

In one of the most important concepts of electrochemistry, electricity can be generated by movements of electrons from the atoms of one element to another in a reaction known as redox or oxidation-reduction reaction. During such reactions, atoms are “oxidized” when they lose an electron and “reduced” when they gain an electron. The commercial value of products and processes supported by oxidation-reduction reactions has led to significant investment in research, especially research of these materials, interfaces, and associated technologies, particularly in research on the nanoscale utilizing electron microscopes.

Experiments and processes utilizing redox reactions are commonly controlled utilizing a potentiostat. A potentiostat is a device that controls the potential between a pair of electrodes in an electrochemical cell while measuring the resulting current flow. At its simplest, a potentiostat can be utilized in a two-electrode system utilizing just a working (of indicator) electrode and a reference electrode. However, often a two-electrode system leads to poor control of the working electrode potential due to the high difficulty associated with having the reference electrode complete the circuit and maintain a constant interfacial potential regardless of current and the lack of compensation for the voltage drop across an electrolyte solution. These effects often lead to a lack of consistent reproducibility, limiting the usefulness thereof in experiments and industrial measurements.

In light of the above difficulties, a potentiostat is often utilized in a three-electrode system utilizing a working electrode, a counter electrode, and a reference electrode. Therein, the potentiostat controls the voltage difference between the working electrode and the reference electrode and measures the current flow between the working and counter electrodes. That is, in a three-electrode system the roles of passing current and maintaining a reference voltage are served by two separate electrodes. Inclusion and use of a reference electrode remedies many of the issues associated with the two-electrode configuration. Indeed, a three-electrode system provides significant benefits in reproducibility providing greater utility in experiments and industrial applications.

One of the most important parts of the three-electrode system is the reference electrode. Ideally, a reference electrode should be stable in a sample solution and have a well defined or known potential over a long period of time. Thereby, the reference electrode, particularly in a three-electrode system, can provide a reference potential for measuring and controlling the potential of the working electrode, without passing any current.

Although various options exist, the most common reference electrode is the silver-silver chloride (Ag/AgCl) reference electrode. Beneficially, Ag/AgCl reference electrodes generally provide stability in results which are not present with various other options. In practice, Ag/AgCl reference electrodes comprise a silver (Ag) wire having an AgCl surface layer immersed in a filling solution, such as a potassium chloride (KCl) solution, which is separated from a sample solution by a porous frit. A frit is a finely porous body of material made by sintering together particles, such as glass, to make a solid but porous body. The frit allows ions to pass between the sample solution and the reference electrode filling solution so that charge balance can be maintained during the electrochemical measurement.

While Ag/AgCl reference electrodes provide many benefits leading to its wide use, there are some significant disadvantages to Ag/AgCl reference electrodes. For example, one disadvantage of the Ag/AgCl reference electrode is that silver and chloride ions can, over time, leak through the frit and into the separated sample solution, leading to contamination. Moreover, other disadvantages exist in miniaturization of a porous frit to a micro and nano scale, as necessary to be part of an in situ microscopy system. Indeed, miniaturization of an Ag/AgCl reference electrode, including the porous frit, produces issues including high impedance and clogging. Indeed, high impedance and clogging can lead to issues with measurements of a potentiostat, such as a noisy signal. Moreover, as the need for precision in resulting measurements increases, environmental noise can also create problematic interference with, i.e., a noisy signal from, an electrochemical system. Accordingly, current reference electrode configurations provide a variety of difficulties which make them not particularly well-suited for small-scale in situ electrochemistry measurements conducted inside a transmission electron microscope (TEM).

Accordingly, a need exists for a reference electrode configuration which overcomes issues with contamination, miniaturization, and noisy signals to be used as part of in situ microscopy systems, such as inside a TEM and which provide superior performance, longevity, and usefulness in electrochemistry.

### SUMMARY

This summary is provided to introduce in a simplified form concepts that are further described in the following detailed descriptions. This summary is not intended to identify key features or essential features of the claimed subject matter, nor is it to be construed as limiting the scope of the claimed subject matter.

An object of the present disclosure is to present a reference electrode assembly for use in a three-electrode system that provides superior performance, longevity and usefulness in electrochemical applications such as by overcoming issues with contamination, miniaturization, and noisy signals and by being particularly useful as part of in situ microscopy systems, such as inside a Transmission Electron Microscope (TEM).

According to at least one embodiment, a reference electrode assembly also includes a micro-electro-mechanical systems (MEMS) chip having a thin-film wire disposed on a surface thereof; a bridge electrode may include a metal wire, the bridge electrode electrically connected to the thin-film wire through a transmission electron microscope (TEM) holder, where at least a portion of the bridge electrode is disposed in contact with a sample solution contained within a vial; and a standard reference electrode having at least a portion thereof disposed within the vial and in contact with the sample solution, where the standard reference electrode is electrically connected to a potentiostat.

In embodiments, reference electrode assembly includes the MEMS chip disposed within a holder tip connected with the TEM holder.

In additional embodiments, the thin-film wire disposed on the surface of the MEMS chip may include at least one of platinum, carbon, and gold.

In further embodiments, the metal wire of the bridge electrode may include at least one of platinum, carbon, and gold.

In certain embodiments, the MEMS chip further includes a working electrode and counter electrode. In various embodiments, the working electrode and counter electrode of the MEMS chip are electrically connected to the potentiostat.

In particular embodiments, the standard reference electrode may be one of a silver-silver chloride (Ag/AgCl) electrode, a saturated calomel electrode, or a copper-copper (II) sulfate electrode.

In yet further embodiments, the portions of the bridge electrode and standard reference electrode disposed within the vial are sealed therein to minimize the impact of noise on the reference potential.

In more embodiments, the reference electrode assembly further includes a Faraday cage with the bridge electrode, the standard reference electrode, and the vial are disposed therein.

In additional embodiments, the Faraday cage is affixed to the handle of the TEM holder. Indeed, the Faraday cage is removably affixed to the handle of the TEM holder in certain embodiments.

In particular embodiments, the Faraday cage is disposed within the handle portion of the TEM holder.

Moreover, the vial is disposed within a handle portion of the TEM holder in certain embodiments.

Additionally, the vial is removably affixed to the handle portion of the TEM holder in various embodiments.

### BRIEF DESCRIPTION OF THE DRAWINGS

The foregoing, as well as the following Detailed Description, is better understood when read in conjunction with the appended drawings. For the purposes of illustration, there is shown in the drawings exemplary embodiments; however, the presently disclosed subject matter is not limited to the specific methods and instrumentalities disclosed.

The embodiments illustrated, described, and discussed herein are illustrative of the present invention. As these embodiments of the present invention are described with reference to illustrations, various modifications or adaptations of the methods and or specific structures described may become apparent to those skilled in the art. It will be appreciated that modifications and variations are covered by the above teachings and within the scope of the appended claims without departing from the spirit and intended scope thereof. All such modifications, adaptations, or variations that rely upon the teachings of the present invention, and through which these teachings have advanced the art, are considered to be within the spirit and scope of the present invention. Hence, these descriptions and drawings should not be considered in a limiting sense, as it is understood that the present invention is in no way limited to only the embodiments illustrated. Embodiments of the present invention are shown with reference to the following drawings introduced as follows:

FIG. 1 is diagrammatic view of a reference electrode assembly utilizing a “pseudo reference” electrode to perform electrochemical measurements on a sample solution within a transmission electron microscope (TEM);

FIG. 2 is a top plan view of a MEMS Chip having a thin film wires deposited thereupon for the reference, counter, and working electrode connections;

FIG. 3 is diagrammatic view of a reference electrode assembly according to one or more embodiments herein that may be utilized to perform electrochemical measurements on a sample solution within a TEM;

FIG. 4 a diagrammatic view of a reference electrode assembly according to one or more embodiments herein wherein the vial, its sample solution, the standard reference electrode, and the bridge electrode are all located within a Faraday cage;

FIG. 5 is a diagrammatic view of a reference electrode assembly according to one or more embodiments herein wherein the vial is formed into the handle of the TEM holder;

FIG. 6 is a diagrammatic view of a reference electrode assembly according to one or more embodiments herein wherein the Faraday cage, and its contents are formed into the handle of the TEM holder; and

FIG. 7 is a diagrammatic view of a reference electrode assembly according to one or more embodiments herein wherein the vial includes a filling solution therein and the MEMS Chip contacts a sample solution.

ELEMENT REFERENCE NUMBERS

| | |
|---|---|
| 100 | Reference Electrode Assembly |
| 102 | Micro-Electro-Mechanical Systems (MEMS) Chip |
| 104 | Reference Electrode Connection |
| 106 | Working Electrode Connection |
| 108 | Counter Electrode Connection |
| 110 | Thin-Film Wire |
| 112 | Bridge Electrode |
| 114 | Electrical Connection |
| 116 | Transmission Electron Microscope (TEM) holder |
| 118 | Potentiostat |
| 120 | Standard Reference Electrode |
| 122 | Container |
| 124 | Sample Solution |
| 126 | Filling Solution |
| 128 | Holder Tip |
| 130 | Seal |
| 132 | Faraday Cage |
| 134 | Handle Portion |

### DETAILED DESCRIPTION

The following description and figures are illustrative and are not to be construed as limiting. Numerous specific details are described to provide a thorough understanding of the disclosure. In certain instances, however, well-known, or conventional details are not described to avoid obscuring the description. Reference in this specification to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not for other embodiments.

The terms used in this specification generally have their ordinary meanings in the art, within the context of the disclosure, and in the specific context where each term is used. Certain terms that are used to describe the disclosure are discussed below, or elsewhere in the specification, to provide additional guidance to the practitioner regarding the description of the disclosure. It will be appreciated that same thing can be said in more than one way.

Alternative language and synonyms may be used for any one or more of the terms discussed herein. No special significance is to be placed upon whether a term is elaborated on or discussed herein. Synonyms for certain terms are provided. A recital of one or more synonyms does not exclude the use of other synonyms. The use of examples anywhere in this specification, including examples of any terms discussed herein, is illustrative only, and is not intended to further limit the scope and meaning of the disclosure or of any exemplified term. Likewise, the disclosure is not limited to various embodiments given in this specification.

Without intent to limit the scope of the disclosure, examples of instruments, apparatus, methods, and their related results according to the embodiments of the present disclosure are given below. Note that titles or subtitles may be used in the examples for convenience of a reader, which in no way should limit the scope of the disclosure.

In embodiments, a typical three electrode system to perform electrochemical measurements with a potentiostat includes a working electrode, a counter electrode, and a reference electrode. One of the most common reference electrodes utilized for electrochemical measurements is a silver-silver chloride (Ag/AgCl) electrode. An Ag/AgCl electrode typically has a silver (Ag) wire with a layer of silver chloride (AgCl) on its surface. In general practice, this wire is immersed in a filling solution, such as a potassium chloride (KCl) solution, which is separated from a sample solution by a porous frit. Generally, a frit is a finely porous body of material made by sintering together particles, such as glass, to make a solid but porous body. Accordingly, a frit allows ions to pass between the sample solution and the reference electrode filling solution so that charge balance can be maintained during the electrochemical measurement. While an Ag/AgCl electrode offers good performance and has advantages related to its use, it has disadvantages to its use and cannot be easily or usefully miniaturized. Indeed, in instances and embodiments where electrochemical measurements are to be performed within a transmission electron microscope (TEM), one common issue related to miniaturization involves the increased risk of clogging and high impedance related to smaller porous frits.

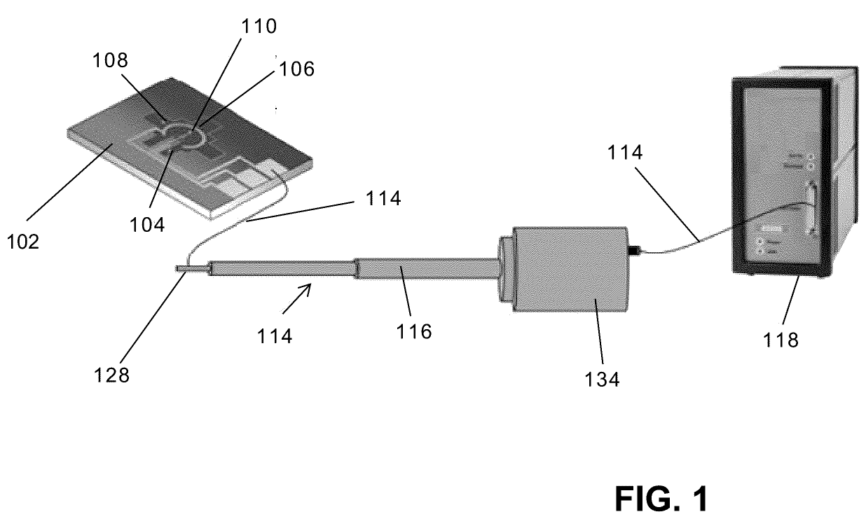

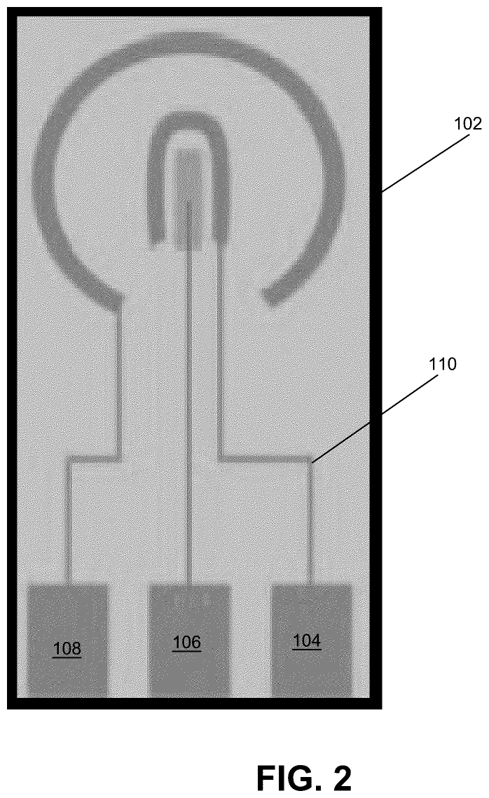

Accordingly, alternative reference electrode assembly embodiments are generally utilized for electrochemistry at the small (micro or nano) scale involving what are commonly identified as “pseudo-reference” electrodes, as shown in FIG. 1. In general, pseudo-reference electrodes are simply metal wires immersed in the sample solution. For TEM related assembly embodiments, pseudo-reference electrodes often comprise a thin-film wire 110, made of a metal such as platinum, on a Micro-Electro-Mechanical Systems (MEMS) chip 102 as a reference electrode connection 104 along with similar wires for the working electrode connection 106 and counter electrode connection 108, as in FIG. 2. In embodiments, the reference electrode connection 104 is then connected to a potentiostat 118 such as through an electrical connection 114 routed through a TEM holder 116. In embodiments, the MEMS chip 102 may be housed within a holder tip 128 affixed to or disposed at (or within) a TEM holder 116 as in FIG. 1.

In general, pseudo-reference electrodes can provide a constant potential, the reference potential is unknown and value dependent on the composition of the sample solution. Consequently, redox potentials measured using a pseudo-reference electrode must be quoted relative to redox potential of an internal reference with a known potential, like ferrocene in embodiments. Moreover, pseudo-reference electrodes are also prone to reference potential drift. Therefore, while pseudo-reference electrodes made from metal wires are simpler to manufacture and integrate compared to standard references, particularly in TEM related applications, their instability can lead to ambiguous experimental results and a large amount of uncertainty in measured potentials in embodiments.

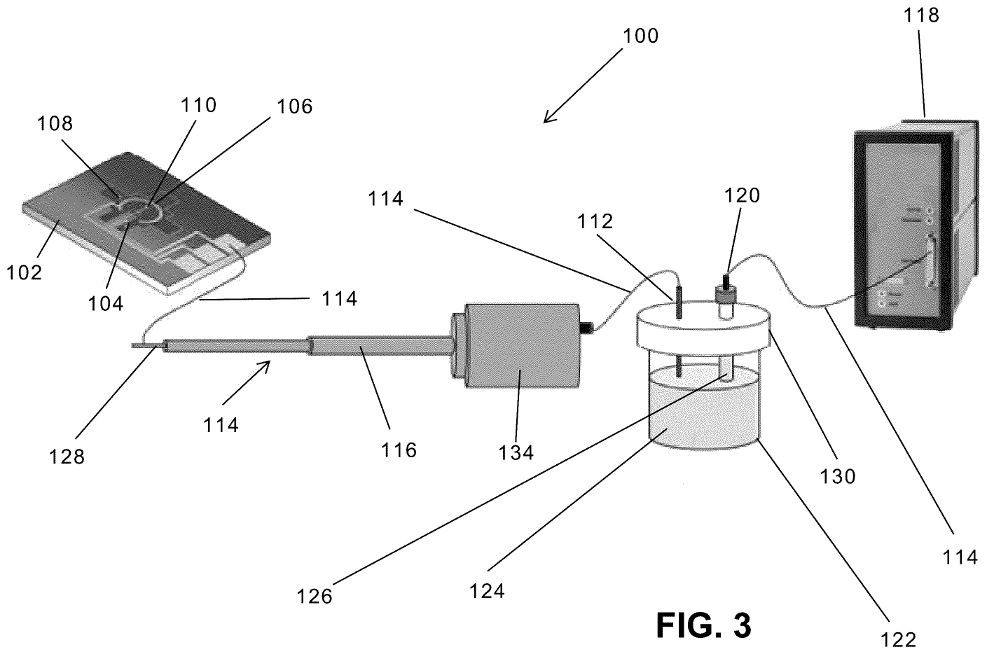

In at least one embodiment, a reference electrode assembly 100 is provided, as shown in FIG. 3, which utilizes a bipolar reference electrode as an alternative to, and improvement in TEM related applications over, a miniaturized standard Ag/AgCl reference electrode and the above-described pseudo-reference electrode. Similar to the embodiment of FIG. 1, the assembly 100 includes a MEMS chip 102 having thin-film wires 110 for the reference electrode connection 104, working electrode connection 106, and counter electrode connection 108 where the reference electrode connection 104 is connected to a potentiostat 118 through an electrical connection 114 routed though a TEM holder 116. However, the electrical connection is also routed through an intervening bridge electrode 112 having a portion disposed in a container 122, such as a vial, of sample solution 124 in contact with a portion of a standard reference electrode 120 that is in electrical connection to the potentiostat 118, as shown in FIG. 2. Thereby, the assembly 100 creates a bipolar reference electrode allowing a standard reference electrode 120, such as a Ag/AgCl reference electrode, to be utilized in TEM related applications without requiring miniaturization of portions thereof, including the frit, which can be problematic when miniaturized.

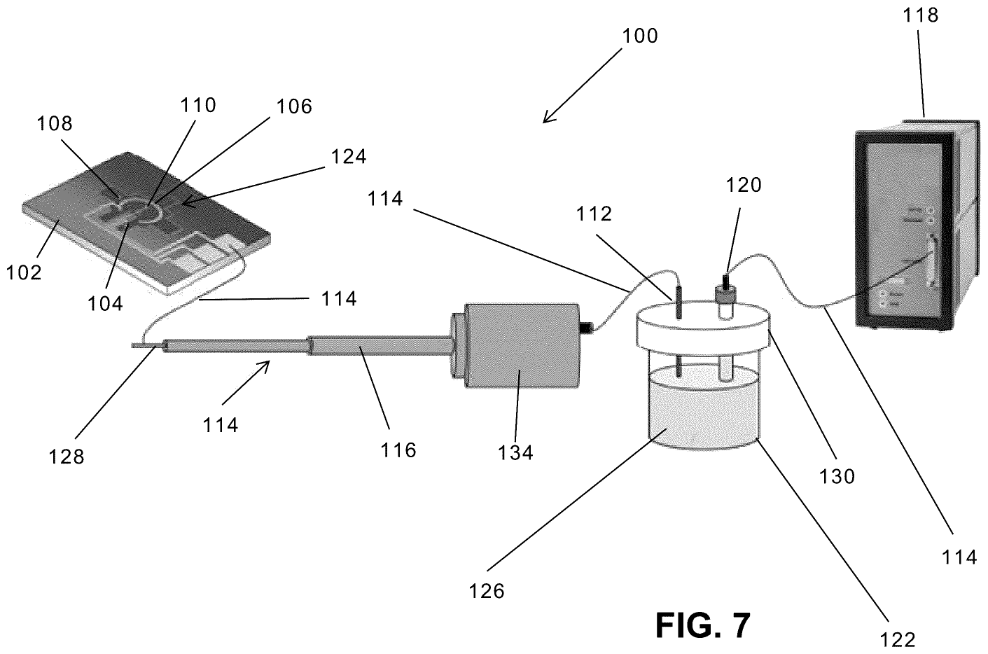

In embodiments, the bridge electrode 112 may be composed of one of platinum (as in FIG. 2), carbon, or gold. In further embodiments, the standard reference electrode 120 may be an Ag/AgCl reference electrode (as in FIG. 3), a saturated calomel electrode, a copper-copper (II) sulfate electrode, or a standard hydrogen electrode. Moreover, the container 122, such as a vial, may have a seal 130 connected thereupon so the contents of the container 122 are secured within in embodiments, as in FIGS. 3-6. Moreover, that seal 130 may be removably affixed to the body of the container 122 in further embodiments. Additionally, the container 122 may contain a sample solution 124 in embodiments. However, it is foreseen that in certain embodiments, the container 122 may house a filling solution 126 which is similar to or the same as the filing solution 126 within an Ag/AgCl standard reference electrode, identified in FIG. 3. Indeed, the filing solution 126 may be potassium chloride (KCl) in embodiments and may be 1-3 M KCl in particular embodiments. Moreover, in embodiments the container 122 and filing solution 126 may also comprise solid KCl to ensure that the filing solution 126 is saturated with Cl ions. Thereby, in embodiments, the reference electrode assembly herein can accommodate liquid electrochemistry experiments with the sample solution 124 disposed in contact with the MEMS Chips 102, as in FIG. 7. In embodiments, the sample solution 124 may be enclosed between a pair of MEMS Chips 102 to isolate the sample solution 124 in an environment separate from the high vacuum that may be generated in a TEM. In embodiments having a pair of MEMS Chips 102, at least one of the MEMS Chips 102 the aforementioned working, counter, and reference electrodes.

In certain embodiments, the thin-film wire 110 is made of or with platinum, as in FIG. 1. However, any suitable material is capable of being utilized on a MEMS chip 102. Indeed, it is foreseen that the thin-film wire 110 may be composed of gold or carbon in embodiments. Moreover, the working electrode connection 106 and counter electrode connections 108 on a MEMS chip 102 are also connected to a potentiostat 118 in embodiments. Similarly, the working electrode 106 and counter electrode 108 may be selected, in embodiments, for their suitability to engage in the desired redox reactions. Generally, both the working and counter electrodes comprise chemically stable materials, such as platinum or glassy carbon, in embodiments. In embodiments, the surface area of the counter electrode 108 should be significantly greater than that of the working electrode. Indeed, more of the counter electrode 108 material may be deposited on the MEMS chip 102, ensuring a greater amount of surface area. In embodiments, the counter electrode 108 can perform the opposite reaction to that occurring at the working electrode 106. For example, if aluminum reduction is occurring at the working electrode 106, a high-quality aluminum counter electrode 108 may be used, with the expectation that aluminum oxidation will be the dominant reaction occurring at the counter electrode 108. Thereby, a net zero change in solution composition may be maintained in embodiments, e.g. the aluminum ions removed from solution at the working electrode 106 are replaced into solution from an aluminum counter electrode 108.

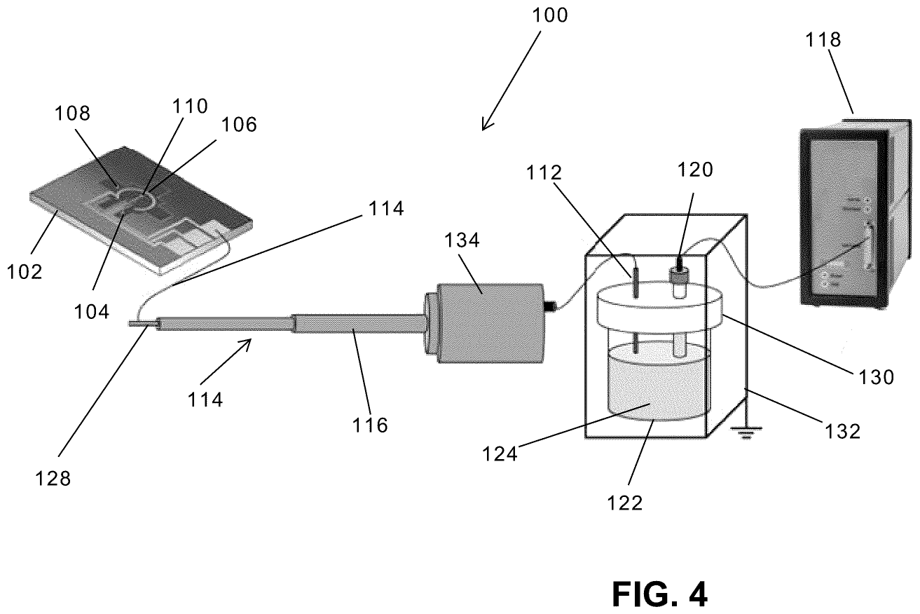

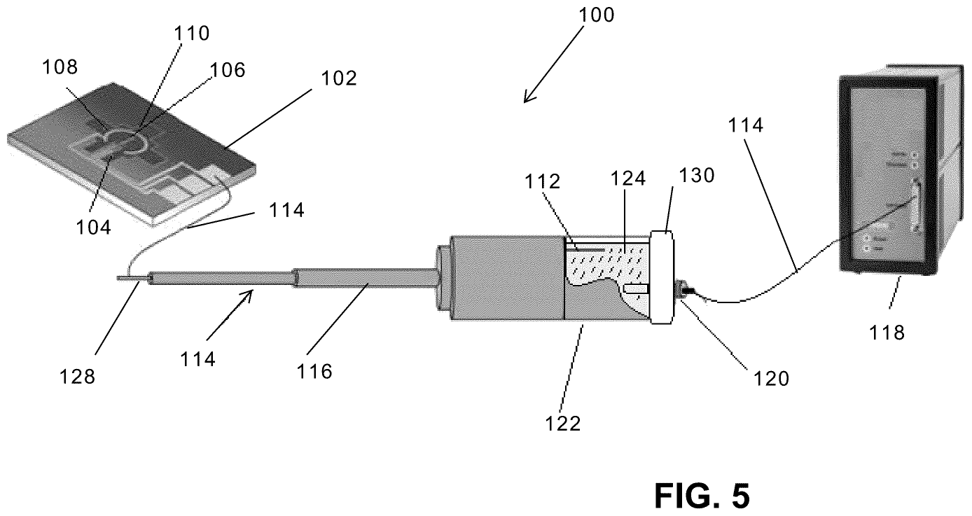

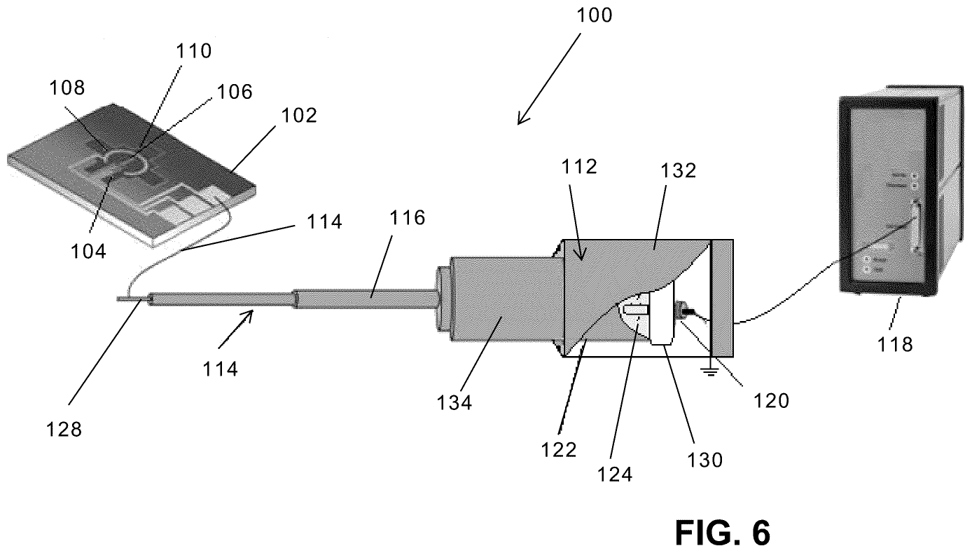

In particular embodiments, the reference electrode assembly 100 further comprises a Faraday cage 132 that encloses the bridge electrode 112, the standard reference electrode 120, and the container 122 therein, as in FIGS. 4 and 6. In embodiments, the Faraday cage 132 may be affixed to or disposed within a handle portion 134 of the TEM holder 116, as in FIG. 6. Indeed, in embodiments, the Faraday cage 132 may be removable attached to the TEM holder 116, such as to its handle portion 134. In further embodiments of the reference electrode assembly 100, the container 122 may be disposed within the TEM holder 116, such as in a handle portion 134, as in FIGS. 5 and 6. Indeed, the container 122 may be removably affixed to the TEM holder 116 in embodiments.

In embodiments, the disclosed assembly 100 can utilize any number of commercially available standard reference electrodes, allowing the user the ability to employ conventional reference electrodes and eliminate cross contamination of their experiment from reference electrode leakage. Moreover, in embodiments, the disclosed assembly 100, the bridge connection 112, optionally shielded, connects the on-chip reference electrode 104 to an external electrolyte solution 126 containing a standard reference electrode 120, optionally shielded from noise and interference by a dedicated Faraday cage 132. In embodiments, the Faraday cage 132 may further comprise passthroughs that minimize mechanical and electronic interference. Moreover, the TEMs holder 116 may also include shielding, such as a Faraday cage, to shield a bridge connection 112 passing therethrough. Thereby, in embodiments, the assembly 100 utilizes the bridge connection 112 to allow conduction between the active electrochemical cell, including the MEMS chip 102, inside the TEM and a shielded electrolyte cell containing the reference electrode located externally to the TEM.

Any dimensions expressed or implied in the drawings and these descriptions are provided for exemplary purposes. Thus, not all embodiments within the scope of the drawings and these descriptions are made according to such exemplary dimensions. The drawings are not necessarily made to scale. Thus, not all embodiments within the scope of the drawings and these descriptions are made according to the apparent scale of the drawings regarding relative dimensions in the drawings. However, for each drawing, at least one embodiment is made according to the apparent relative scale of the drawing.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present inventive subject matter. As used herein, the term “and/or” includes all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will be understood that when an element or layer is referred to as being “on” another element or layer, the element or layer can be directly on another element or layer, or intervening elements or layers may also be present. In contrast, when an element is referred to as being “directly on” another element or layer, there are no intervening elements or layers present. As used herein, the term “and/or” includes all combinations of one or more of the associated listed items.

Spatially relative terms, such as “below,” “beneath,” “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation, in addition to the orientation depicted in the figures. Throughout the specification, like reference numerals in the drawings denote like elements.

Embodiments of the inventive subject matter are described herein with reference to plan and perspective illustrations that are schematic or diagrammatic illustrations of idealized embodiments of the inventive subject matter. As such, variations from the shapes of the illustrations as a result, for example, of manufacturing techniques and/or tolerances, are to be expected. Thus, the inventive subject matter should not be construed as limited to the shapes of objects illustrated herein, but should include deviations in shapes that result, for example, from manufacturing. Thus, the objects illustrated in the figures are schematic in nature and their shapes are not intended to illustrate the actual shape of a region of a device and are not intended to limit the scope of the inventive subject matter.

The terminology used herein is for the purpose of describing embodiments only and is not intended to be limiting of the present inventive subject matter. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this present inventive subject matter belongs. It will be further understood that terms used herein should be interpreted as having a meaning that is consistent with their meaning in the context of this specification and the relevant art and will not be interpreted in an idealized or overly formal sense unless expressly so defined herein. The term “plurality” is used herein to refer to two or more of the referenced items. Although any methods, devices, and materials similar or equivalent to those described herein can be used in the practice or testing of the presently disclosed subject matter, representative methods, devices, and materials are now described.

In the drawings and specification, there have been disclosed typical preferred embodiments of the inventive subject matter and, although specific terms are employed, they are used in a generic and descriptive sense only and not for purposes of limitation, the scope of the inventive subject matter being set forth in the following claims.

What is claimed is:

1. A reference electrode assembly for electrochemistry microscopy samples, the reference electrode assembly comprising:
at least one Micro-Electro-Mechanical Systems (MEMS) chip having a thin-film wire disposed on a surface thereof configured to act as a reference electrode;
a bridge electrode comprising a metal wire, the bridge electrode electrically connected to the thin-film wire through a Transmission Electron Microscope (TEM) holder,
wherein at least a portion of the bridge electrode is disposed in contact with a sample solution contained within a container; and
a standard reference electrode having at least a portion thereof disposed within the container and in contact with the sample solution,
wherein the standard reference electrode is electrically connected to a potentiostat.

2. The reference electrode assembly of claim 1, wherein the at least one MEMS chip is disposed within a holder tip connected with the TEM holder.

3. The reference electrode assembly of claim 1, wherein the thin-film wire disposed on the surface of the MEMS chip comprises platinum.

4. The reference electrode assembly of claim 1, wherein the thin-film wire disposed on the surface of the MEMS chip comprises one of carbon and gold.

5. The reference electrode assembly of claim 1, wherein the metal wire of the bridge electrode comprises platinum.

6. The reference electrode assembly of claim 1, wherein the metal wire of the bridge electrode comprises one of carbon and gold.

7. The reference electrode assembly of claim 1, wherein the at least one MEMS chip further comprises additional thin film metal elements configured to be each of a working electrode and a counter electrode.

8. The reference electrode assembly of claim 7, wherein the working electrode and counter electrode are electrically connected to the potentiostat.

9. The reference electrode assembly of claim 1, wherein the standard reference electrode comprises a silver-silver chloride (Ag/AgCl) electrode.

10. The reference electrode assembly of claim 1, wherein the standard reference electrode comprises a saturated calomel electrode.

11. The reference electrode assembly of claim 1, wherein the standard reference electrode comprises a copper-copper (II) sulfate electrode.

12. The reference electrode assembly of claim 1, wherein the portion of the bridge electrode and the standard reference electrode disposed within the container are sealed therein.

13. The reference electrode assembly of claim 1, further comprising a Faraday cage, wherein at least a portion of the bridge electrode, the standard reference electrode, and the container are disposed within the Faraday cage, configured to minimize noise effects on a reference potential.

14. The reference electrode assembly of claim 13, wherein the Faraday cage is affixed to a handle portion of the TEM holder.

15. The reference electrode assembly of claim 14, wherein the Faraday cage is removably affixed to a handle portion of the TEM holder.

16. The reference electrode assembly of claim 13, wherein Faraday cage is disposed within a handle portion of the TEM holder.

17. The reference electrode assembly of claim 1, wherein the container is disposed within a handle portion of the TEM holder.

18. The reference electrode assembly of claim 1, wherein the container is removably affixed to a handle portion of the TEM holder.
